(19) United States
(12) Patent Application Publication
(10) Pub. No.: US 2025/0017033 A1
(43) Pub. Date: Jan. 9, 2025

(54) QUANTUM DOTS LIGHT-EMITTING DEVICE AND MANUFACTURING METHOD THEREOF

(71) Applicant: BOE TECHNOLOGY GROUP CO., LTD.

(72) Inventors: Di ZHANG, Beijing (CN); Yang GAO, Beijing (CN); Xu YUAN, Beijing (CN); Zhuo LI, Beijing (CN); Zhuo CHEN, Beijing (CN)

(73) Assignee: BOE TECHNOLOGY GROUP CO., LTD., Beijing (CN)

(21) Appl. No.: 18/278,674

(22) PCT Filed: May 23, 2022
(86) PCT No.: PCT/CN2022/094553

§ 371 Date: Aug. 24, 2023

(51) Int. Cl. H10K 50/115; B82Y 20/00; B82Y 40/00; C09K 11/02; H10K 50/16; H10K 71/15; H10K 71/40; H10K 85/30; H10K 102/00

(52) U.S. Cl. CPC H10K 50/115; C09K 11/025; H10K 50/16; H10K 71/15; H10K 71/441; H10K 85/30; B82Y 20/00; B82Y 40/00; H10K 2102/351; H10K 2102/361

(57) ABSTRACT

A quantum dots light-emitting device and a manufacturing method thereof are provided, which includes: an electron transport layer, an auxiliary layer, and a quantum dot light-emitting layer sequentially stacked, the quantum dot light-emitting layer includes quantum dots, surfaces of the quantum dots are provided with a first ligand, the first ligand includes a first functional group connected to the quantum dots and a second functional group away from the quantum dots; surfaces of the quantum dots in contact with the first ligand have a compound formed by a metal element and a nonmetallic element, a material of the auxiliary layer includes at least one selected from a group consisting of a compound containing the second functional group, a compound containing the metal element, and a compound containing the nonmetallic element. The auxiliary layer firstly occupies a site where unnecessary quantum dots may remain.

### TECHNICAL FIELD

At least one embodiment of the present disclosure relates a quantum dots light-emitting device and a manufacturing method thereof.

### BACKGROUND

A quantum dots light-emitting display (QLED) is a new display technology based on organic light-emitting displays. Different from other types of organic light-emitting diodes, QLED has a quantum dot layer as an electrolight-emitting structure, and the principle of the QLED is that electrons are injected into the quantum dot layer through the electron transport layer, holes are injected into the quantum dot layer through the hole transport layer, and electrons and holes are combined to emit light in the quantum dot.

Quantum dots (QD), as a new light-emitting material, have the advantages of high light color purity, high luminous quantum efficiency, adjustable luminous color, and long service life, and have become the research focus of new light-emitting materials. Therefore, quantum dot light-emitting diode (QLED) with quantum dot material as light-emitting layer has become the main research direction of new display devices. With the continuous improvement of quantum efficiency, QLED devices can achieve a smaller area of light emission, which is conducive to achieving higher resolution of display products.

### SUMMARY

The embodiments of the present disclosure provide a quantum dot light-emitting device and a manufacturing method thereof. In the quantum dot light-emitting device, the first ligand on a surface of the quantum dot includes a first functional group connected to the quantum dot and a second functional group away from the quantum dot, and the surface of the quantum dot in contact with the first ligand has a compound formed by a metal element and a nonmetallic element, by providing an auxiliary layer located between an electron transport layer and a quantum dot light-emitting layer and making the auxiliary layer have a material of at least one selected from the group consisting of a compound containing the second functional group, a compound containing the metal element, and a compound containing the nonmetallic element, the auxiliary layer occupies a site where unnecessary quantum dots may remain, so that the unnecessary quantum dots can be easily removed from the electron transport layer, so as to reduce the risk of color mixing of the quantum dot light-emitting device, thereby improving the full-color performance of the quantum dot light-emitting device.

At least one embodiment of the present disclosure provides a quantum dot light-emitting device, and the quantum dot light-emitting device comprises: an electron transport layer, an auxiliary layer, and a quantum dot light-emitting layer which are sequentially stacked, in which the quantum dot light-emitting layer comprises quantum dots, and surfaces of the quantum dots are provided with a first ligand, and the first ligand comprises a first functional group connected to the quantum dots and a second functional group away from the quantum dots; surfaces of the quantum dots in contact with the first ligand have a compound formed by a metal element and a nonmetallic element, and a material of the auxiliary layer comprises at least one selected from a group consisting of a compound containing the second functional group, a compound containing the metal element, and a compound containing the nonmetallic element.

For example, in the quantum dot light-emitting device provided by the embodiment of the present disclosure, the second functional group is an amino group, and the compound containing the second functional group comprises compounds of alkyl fatty amines with less than 7 carbon atoms, compounds of aromatic amines with electron transport properties, compounds of aminosilane coupling agents, and compounds of quaternary ammonium salts.

For example, in the quantum dot light-emitting device provided by the embodiment of the present disclosure, the compounds of alkyl fatty amines with less than 7 carbon atoms comprise at least one selected from the group consisting of ethylamine, propylamine and butylamine; the compounds of aromatic amines with electron transport properties comprise at least one selected from the group consisting of aniline, phenylethylamine and amphetamine; the compounds of aminosilane coupling agents comprise N-β-(aminoethyl)-γ-aminopropyl methyl dimethoxysilane; the compounds of quaternary ammonium salts comprise at least one selected from the group consisting of tetramethylammonium chloride and tetraethylammonium chloride.

For example, in the quantum dot light-emitting device provided by the embodiment of the present disclosure, the first ligand is formed by the reaction of a second ligand under ultraviolet irradiation with an acid generator, and a structural formula of the first ligand comprises

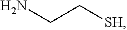

and a structural formula of the second ligand comprises

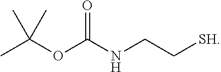

For example, in the quantum dot light-emitting device provided by the embodiment of the present disclosure, the material of the auxiliary layer comprises nanoparticles with the metal element or nanoparticles with the nonmetallic element.

For example, in the quantum dot light-emitting device provided by the embodiment of the present disclosure, a photoluminescence quantum yield of the nanoparticles with the metal element and a photoluminescence quantum yield of the nanoparticles with the nonmetallic element are both less than 2%.

For example, in the quantum dot light-emitting device provided by the embodiment of the present disclosure, a size of each of the nanoparticles with the metal element and a size of each of the nanoparticles with the nonmetallic element are both smaller than a size of each of the quantum dots.

For example, in the quantum dot light-emitting device provided by the embodiment of the present disclosure, each of the quantum dots has a core-shell structure, a material of a shell of each of the quantum dots and a material of a core of each of the quantum dots at least contain a same element, and the material of the auxiliary layer is the same as that of the core of each of the quantum dots.

For example, in the quantum dot light-emitting device provided by the embodiment of the present disclosure, the material of the auxiliary layer comprises nanoparticles formed of a same material of the core of each of the quantum dots, and a size of each of the nanoparticles of the auxiliary layer is the same or substantially the same as that of the core of each of the quantum dots.

For example, in the quantum dot light-emitting device provided by the embodiment of the present disclosure, a material of the quantum dots comprises a compound formed by a plurality of metal cations and an anions, and the compound containing the metal element comprises at least one selected from the group consisting of the plurality of metal cations.

For example, in the quantum dot light-emitting device provided by the embodiment of the present disclosure, a material of the quantum dots comprises a compound formed by a plurality of metal cations and anions, and the compound containing the nonmetallic element comprises the anions.

For example, in the quantum dot light-emitting device provided by the embodiment of the present disclosure, the compound containing the metal element or the compound containing the nonmetallic element comprises at least one selected from the group consisting of CdS, CdSe, InP, PbS, CsPbCl₃, CsPbBr₃ and CsPbI₃.

For example, in the quantum dot light-emitting device provided by the embodiment of the present disclosure, the material of the auxiliary layer comprises a compound containing the second functional group and a compound containing the metal element, and a ratio of a molar concentration of the compound containing the second functional group to a molar concentration of the compound containing the metal element is in a range from 10:1 to 30:1.

For example, in the quantum dot light-emitting device provided by the embodiment of the present disclosure, the material of the auxiliary layer comprises a compound containing the second functional group and a compound containing the nonmetallic element, and a ratio of a molar concentration of the compound containing the second functional group to a molar concentration of the compound containing the nonmetallic element is in a range from 10:1 to 30:1.

For example, in the quantum dot light-emitting device provided by the embodiment of the present disclosure, a thickness of the auxiliary layer is in a range from 1 nm to 5 nm.

For example, in the quantum dot light-emitting device provided by the embodiment of the present disclosure, a material of the electron transport layer comprises at least one selected from a group consisting of zinc oxide, zinc oxide doped with magnesium ions, and zinc oxide doped with cesium ions.

For example, the quantum dot light-emitting device provided by the embodiment of the present disclosure, further comprises a hole transport layer and a hole injection layer, in which the hole transport layer is arranged at a side of the quantum dot light-emitting layer away from the electron transport layer, and the hole injection layer is arranged at a side of the hole transport layer away from the electron transport layer.

For example, the quantum dot light-emitting device provided by the embodiment of the present disclosure, further comprises a first electrode and a second electrode, wherein the first electrode is arranged at a side of the electron transport layer away from the auxiliary layer, and the second electrode is arranged at a side of the hole injection layer away from the electron transport layer.

At least one embodiment of the present disclosure further provides a manufacturing method of a quantum dot light-emitting device, and the manufacturing comprises: providing a base substrate; sequentially forming an electron transport layer and an auxiliary layer on the base substrate, and forming a quantum dot light-emitting layer on the auxiliary layer by a photolithography process, in which the quantum dot light-emitting layer comprises quantum dots, and a surface of each of the quantum dots is provided with a first ligand, and the first ligand comprises a first functional group connected to the quantum dots and a second functional group away from the quantum dots; surfaces of the quantum dots in contact with the first ligand have a compound formed by a metal element and a nonmetallic element, and a material of the auxiliary layer comprises at least one selected from a group consisting of a compound containing the second functional group, a compound containing the metal element, and a compound containing the nonmetallic element.

For example, in the manufacturing method provided by the embodiment of the present disclosure, forming the electron transport layer comprises: applying an ethanol solution comprising ZnMgO nanoparticles or ZnO nanoparticles on the base substrate; baking at 80° C.˜100° C. for 8 min˜12 min.

For example, in the manufacturing method provided by the embodiment of the present disclosure, forming the auxiliary layer comprises: applying an ethanol solution of the compound containing the amino group with a molar concentration of 0.01 mol/L to 0.05 mol/L on the electron transport layer.

For example, the manufacturing method provided by the embodiment of the present disclosure, further comprises: forming a hole transport layer at a side of the quantum dot light-emitting layer away from the electron transport layer, and forming a hole injection layer at a side of the hole transport layer away from the electron transport layer.

For example, the manufacturing method provided by the embodiment of the present disclosure, further comprises: forming a first electrode between the electron transport layer and the base substrate, and forming a second electrode at a side of the hole injection layer away from the electron transport layer.

### BRIEF DESCRIPTION OF DRAWINGS

In order to more clearly explain the technical solution of the embodiments of the present disclosure, the following will briefly introduce the drawings of the embodiments. Obviously, the drawings in the following description only relate to some embodiments of the present disclosure, but not limit the present disclosure.

FIG. 1 is a schematic diagram of a process of patterning a quantum dot layer;

FIG. 2 is a quantum dot pattern formed in the actual process of FIG. 1;

FIG. 3 is a schematic cross-sectional structural view of a quantum dot light-emitting device provided by at least one embodiment of the present disclosure;

FIG. 4 is a schematic cross-sectional structural view of yet another quantum dot light-emitting device provided by at least one embodiment of the present disclosure;

FIG. 5 is a schematic cross-sectional structural view of still another quantum dot light-emitting device provided by at least one embodiment of the present disclosure;

FIG. 6 is a schematic cross-sectional structural view of still another quantum dot light-emitting device provided by at least one embodiment of the present disclosure;

FIG. 7 is a flowchart of a manufacturing method of a quantum dot light-emitting device provided by at least one embodiment of the present disclosure;

FIG. 8 is a flowchart of another manufacturing method of a quantum dot light-emitting device provided by at least one embodiment of the present disclosure; and

FIG. 9 is a schematic diagram of a manufacturing process of a quantum dot light-emitting device provided by at least one embodiment of the present disclosure.

### DETAILED DESCRIPTION

In order to make objects, technical details and advantages of embodiments of the present disclosure clear, the technical solutions of the embodiments will be described in a clearly and fully understandable way in connection with the related drawings of the embodiments of the present disclosure. It is apparent that the described embodiments are just a part but not all of the embodiments of the present disclosure. Based on the described embodiments herein, those skilled in the art can obtain, without any inventive work, other embodiment(s) which should be within the scope of the present disclosure.

Unless otherwise defined, all the technical terms and scientific terms used herein have the same meanings as commonly understood by one of ordinary skill in the art to which the present disclosure belongs. The terms “first.” “second,” etc., which are used in the description and claims of the present disclosure, are not intended to indicate any sequence, amount or importance, but distinguish various components. The terms “comprises,” “comprising.” “includes,” “including.” etc., are intended to specify that the elements or the objects stated before these terms encompass the elements or the objects listed after these terms as well as equivalents thereof, but do not exclude other elements or objects. Similar words such as “connected” or “connected” are not limited to physical or mechanical connection, but can include electrical connection, whether direct or indirect. “Up”, “down”, “left” and “right” are only used to indicate the relative positional relationship. When the absolute position of the described object changes, the relative positional relationship may also change accordingly.

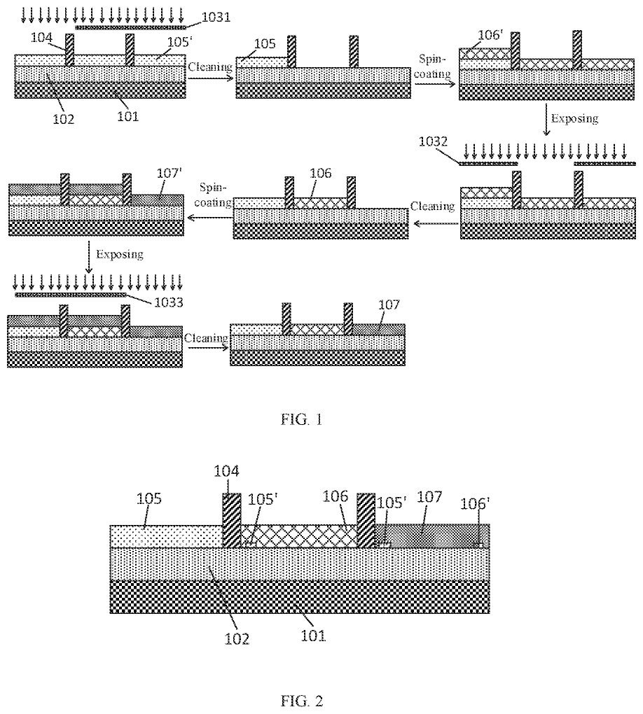

Adopting quantum dots to prepare high-resolution QLED or QD-LCD products has become an important technology. However, in the current quantum dot patterning process, it is easy to cause unnecessary residue of quantum dots after the development process, the problem of color mixing will occur in full-color quantum dot display, which will make the display effect of display devices worse. For example, in the process of preparing a quantum dot light-emitting device, the patterning of quantum dot layer is mainly realized by inkjet printing, but the resolution of patterned quantum dot layer is limited within 200 ppi due to the limitation of inkjet printing equipment. Full-color patterning of quantum dot electroluminescent devices can also be achieved directly by a photolithography process, but this process also has disadvantages, that is, the quantum dots that should be located in the first sub-pixel region remain in the second sub-pixel region, which will lead to the problem of color mixing. For example, FIG. 1 is a schematic diagram of the process of patterning quantum dot layer, as illustrated in FIG. 1, the patterning process includes: providing a base substrate 101, forming a first electrode 102 on the base substrate 101, forming a pixel defining layer 104 at a side of the base substrate 101 where the first electrode 102 is formed, the pixel defining layer 104 including a plurality of openings to form a plurality of sub-pixel regions, and applying a red quantum dot material in each sub-pixel region to form a red quantum dot film layer 105′, performing a patterning process on the red quantum dot film layer 105′ including: shielding the middle sub-pixel region and the rightmost sub-pixel region with a first mask plate 1031, so that light is irradiated to the leftmost sub-pixel region, and the red quantum dot material in the leftmost sub-pixel region is crosslinked, that is, the exposure process of the red quantum dot film layer 105′ being completed, and cleaning the red quantum dot material without cross-linking reaction to remove the red quantum dot material in the middle sub-pixel region and the rightmost sub-pixel region, that is, forming a red quantum dot pattern 105; applying the green quantum dot material in each sub-pixel region to form a green quantum dot film layer 106′, and the process of patterning the green quantum dot film layer 106′ including: shielding the leftmost sub-pixel region and the rightmost sub-pixel region by using a second mask plate 1032, so that light is irradiated to the middle sub-pixel region, and the green quantum dot material in the middle sub-pixel region is crosslinked, that is, the exposure process of the green quantum dot film layer 106′ being completed, and cleaning the green quantum dot material without cross-linking reaction to remove the green quantum dot material in the leftmost sub-pixel region and the rightmost sub-pixel region, that is, the green quantum dot pattern 106 being formed; applying blue quantum dot material in each sub-pixel region to form a blue quantum dot film layer 107′, and the process of patterning the blue quantum dot film layer 107′ including: shielding the leftmost sub-pixel region and the middle sub-pixel region by using a third mask plate 1033, so that light is irradiated to the rightmost sub-pixel region, so that the blue quantum dot material in the rightmost sub-pixel region is crosslinked, that is, the exposure process of the blue quantum dot film layer 107′ being completed, and cleaning the blue quantum dot material without cross-linking reaction to remove the blue quantum dot material in the leftmost sub-pixel region and the middle sub-pixel region, that is, the blue quantum dot pattern 107 is formed.

It should be noted that the process diagram illustrated in FIG. 1 is an ideal process diagram. In each cleaning step, unnecessary quantum dots are removed completely, and there is no quantum dot residue in the region without illumination. However, in the actual manufacturing process, there is always a problem that the quantum dots are not well cleaned in the region where they should be washed away, that is, there will be a problem of quantum dot residue. For example, red quantum dots remain in the middle sub-pixel region and the rightmost sub-pixel region, green quantum dots remain in the rightmost sub-pixel region. For example, FIG. 2 is a quantum dot pattern formed in the actual process of FIG. 1. As illustrated in FIG. 2, the material of red quantum dot film layer 105′ remains at the side of green quantum dot pattern 106 close to the base substrate 101, and the material of the green quantum dot film layer 106′ and the material of the red quantum dot film layer 105′ remain at the side of blue quantum dot pattern 107 close to base substrate 101.

In addition, the quantum dot pattern can also be formed by an indirect photolithography method, that is, the patterning of the quantum dot light-emitting material can be realized by using a sacrificial layer. Specifically, the indirect photolithography method includes forming a sacrificial layer in the area where the quantum dot light-emitting material needs to be removed before forming the quantum dot light-emitting material, and then patterning the quantum dot light-emitting material by using the sacrificial layer elution method. Most indirect photolithography methods also have the case similar to the phenomenon that the green quantum dot material and the blue quantum dot material remain at the side of red quantum dot pattern away from the base substrate, the red quantum dot material remains at the side of the green quantum dot pattern close to the base substrate, the blue quantum dot material remains at the side of the green quantum dot pattern away from the base substrate, and the green quantum dot material and the red quantum dot material remain at the side of the blue quantum dot pattern close to the base substrate. That is, there is a problem that unnecessary quantum dot material cannot be cleaned up by either the direct photolithography method or the indirect photolithography method.

The inventor(s) of the present disclosure found that an auxiliary layer can be formed on a surface of an electron transport layer, and a material of the auxiliary layer is designed to be similar to the ligand on a surface of the quantum dot subject to photosensitive reaction or similar to a material on an outer surface of the quantum dot, so that the auxiliary layer firstly occupies a site where unnecessary quantum dot material may remain, so that unnecessary quantum dot material that may be introduced later will not remain at the site, thereby reducing the phenomenon of color mixing of quantum dot light-emitting devices.

At least one embodiment of the present disclosure provides a quantum dot light-emitting device, which includes: an electron transport layer, an auxiliary layer, and a quantum dot light-emitting layer which are sequentially stacked, the quantum dot light-emitting layer includes quantum dots, and surfaces of the quantum dots are provided with a first ligand, and the first ligand includes a first functional group connected to the quantum dots and a second functional group away from the quantum dots; surfaces of the quantum dots in contact with the first ligand has a compound formed by a metal element and a nonmetallic element, and a material of the auxiliary layer includes at least one selected from a group consisting of a compound containing the second functional group, a compound containing the metal element, and a compound containing the nonmetallic element, and a material of the auxiliary layer is designed to be similar to a ligand on the surfaces of the quantum dots subject to photosensitive reaction or similar to a material on outer surfaces of the quantum dots, so that the auxiliary layer firstly occupies a site where unnecessary quantum dot material may remain, and unnecessary quantum dot material that may be introduced later will not remain at the site, thereby reducing the phenomenon of color mixing of the subsequently formed quantum dot light-emitting devices, improving the color gamut of the subsequently formed quantum dot light-emitting devices, and further improving the full-color performance of the quantum dot light-emitting devices.

For example, the compound formed by the metal element and the nonmetallic element may be an ionic compound or a covalent compound, which is not limited by the embodiment of the present disclosure.

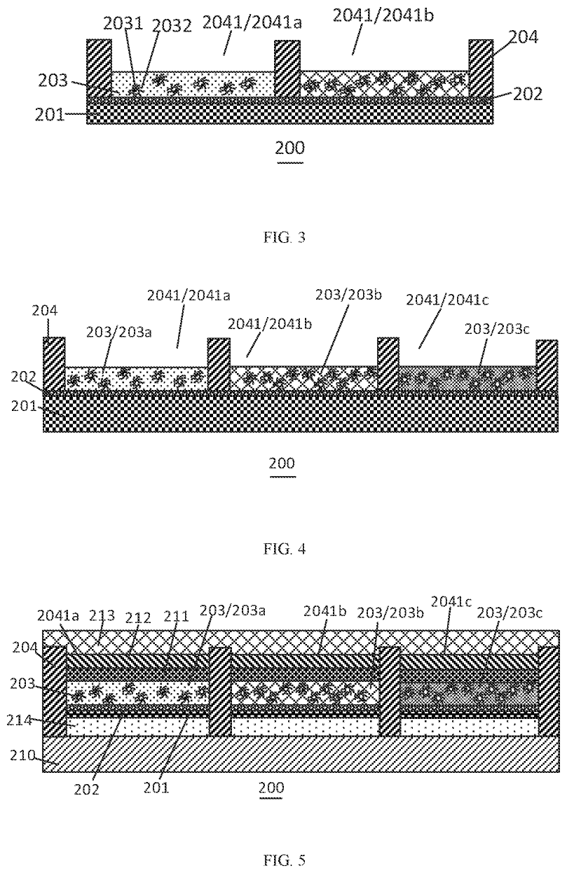

For example, FIG. 3 is a schematic cross-sectional structural view of a quantum dot light-emitting device provided by at least one embodiment of the present disclosure. As illustrated in FIG. 3, the quantum dot light-emitting device 200 includes an electron transport layer 201, an auxiliary layer 202, and a quantum dot light-emitting layer 203 which are sequentially stacked, and the quantum dot light-emitting layer 203 includes quantum dots 2031, and surfaces of the quantum dots 2031 have a first ligand 2032, and the first ligand 2032 includes a first functional group connected to the quantum dots 2031 and a second functional group away from the quantum dots 2031. The surface of the quantum dots 2031 in contact with the first ligand 2032 has a compound formed by a metal element and a nonmetallic element, and a material of the auxiliary layer 202 includes at least one selected from the group consisting of a compound containing the second functional group, a compound containing the metal element, and a compound containing the nonmetallic element, and the material of the auxiliary layer is designed to be similar to the ligand on the surface of the quantum dot subject to a photosensitive reaction or similar to a material on the outer surface of the quantum dot, so that the auxiliary layer firstly occupies a site where unnecessary quantum dot materials may remain, so that unnecessary quantum dot materials that may be introduced later will not remain at the site, thereby reducing the phenomenon of color mixing of the subsequently formed quantum dot light-emitting devices, improving the color gamut of the subsequently formed quantum dot light-emitting devices, and further improving the full-color performance of the quantum dot light-emitting devices.

It should be noted that, FIG. 3 only schematically illustrates the structure of a quantum dot light-emitting device. In the structure illustrated in FIG. 3, only quantum dot light-emitting layers 203 of two different colors are illustrated, and only part of the quantum dots 2031 and the first ligand 2032 on the surfaces of the quantum dots 2031 are illustrated in the quantum dot light-emitting layers 203 of each color. The quantum dot light-emitting layers 203 of two different colors are separated by a pixel defining layer 204. The quantum dot light-emitting device 200 may also include quantum dot light-emitting layers 203 of other colors, and the quantum dot light-emitting layer 203 can also be completely formed by cross-linked quantum dots, that is, the quantum dot light-emitting layer 203 is formed by closely arranged cross-linked quantum dots, and gaps between adjacent quantum dots are only schematically illustrated in the figure.

It should also be noted that, in the structure illustrated in FIG. 3, the pixel defining layer 204 is directly formed on the auxiliary layer 202. In other exemplary embodiments, the pixel defining layer 204 can also be directly formed on the base substrate, which is not limited by the embodiment of the present disclosure, and the base substrate is not illustrated in FIG. 3.

For example, as illustrated in FIG. 3, the pixel defining layer 204 includes a plurality of openings to form a plurality of sub-pixel regions 2041 which are spaced apart from each other, and the sub-pixel regions 2041 include at least a first sub-pixel region 2041a and a second sub-pixel region 2041b, and quantum dot light-emitting layers 203 of different colors are formed in different sub-pixel regions 2041. For example, in an exemplary embodiment, a red quantum dot light-emitting layer may be formed in the first sub-pixel region 2041a and a green quantum dot light-emitting layer may be formed in the second sub-pixel region 2041b. That is, there are red quantum dots in the first sub-pixel region 2041a and green quantum dots in the second sub-pixel region 2041b.

For example, in the structure illustrated in FIG. 3, because the auxiliary layer 202 is provided between the electron transport layer 201 and the quantum dot light-emitting layer 203, there is no red quantum dot residue in the second sub-pixel region 2041b, so there is no problem of color mixing, so that the color gamut of the quantum dot light-emitting device can be improved, and the full-color performance of the quantum dot light-emitting device can be further improved.

For example, the process of forming the pixel defining layer 204 includes: depositing a material of the pixel defining layer, then applying a photoresist material on the material of the pixel defining layer, exposing and developing the photoresist material with a mask to form a photoresist pattern, then etching the material of the pixel defining layer with the photoresist pattern as a mask to form the pixel defining layer, forming a plurality of openings at the etched part of the material of the pixel defining layer, and forming a plurality of sub-pixel regions 2041 at positions corresponding to the plurality of openings, and the sub-pixel regions 2041 are spaced apart from each other so that they at least include a first sub-pixel region 2041a and a second sub-pixel region 2041b that are spaced apart from each other.

It should be noted that, although only two openings are illustrated in FIG. 3, the embodiment of the present disclosure is not limited to this, and there may be more openings, that is, there may be more sub-pixel regions 2041. The quantum dot light-emitting device may also include other layer structures, such as electrode structures, and only part of the layer structures are illustrated in FIG. 3 for simplicity.

For example, in an exemplary embodiment, the first functional group connected to the quantum dots 2031 included in the first ligand 2032 is sulfhydryl, and the second functional group away from the quantum dots 2031 included in the first ligand 2032 is amino, and sulfhydryl is more easily connected to the quantum dot than the amino, and amino is more easily exposed at the side away from the quantum dot.

For example, the structural formula of the first ligand 2032 includes

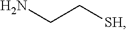

in the presence of an acid generator, the first ligand is formed by the reaction of a second ligand, which is tert-butyl N-(2-mercaptoethyl) carbamate, and the structural formula of the second ligand is

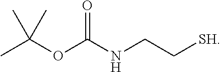

For example, the reaction formula of the second ligand to form the first ligand is:

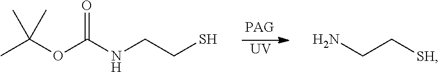

where PAG is an acid generator and its structure is

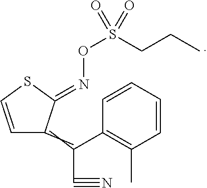 [SMILES: CCCS(=O)(=O)O/N=C1\SC=CC1=C(C#N)c1ccccc1C]

For example, the compound containing the second functional group includes at least one selected from the group consisting of compounds of alkyl fatty amines with less than 7 carbon atoms, compounds of aromatic amines with electron transport performance, compounds of aminosilane coupling agents, and compounds of quaternary ammonium salts.

For example, in an exemplary embodiment, the compounds of alkyl fatty amines with less than 7 carbon atoms include at least one selected from a group consisting of ethylamine, propylamine, and butylamine. The compound of aromatic amine with electron transport performance includes at least one selected from a group consisting of aniline, phenylethylamine, and amphetamine. The compound of aminosilane coupling agent includes N-β-(aminoethyl)-γ-aminopropyl methyl dimethoxysilane, and the compound of quaternary ammonium salt includes at least one selected from the group consisting of tetramethylammonium chloride, and tetraethylammonium chloride.

It should be noted that, choosing the compounds of alkyl fatty amines with less than 7 carbon atoms can ensure that the carbon skeleton is small enough so that the auxiliary layer can be better inserted.

For example, in the case where the auxiliary layer in a quantum dot light-emitting device is made of four materials, namely butylamine, amphetamine, N-β-(aminoethyl)-γ-aminopropyl methyl dimethoxysilane, and tetraethylammonium chloride, respectively, and the quantum dot light-emitting device after being developed is tested by ICP-MS respectively, different levels of Cd residues on the quantum dot light-emitting device are obtained. It is found that the residual amount of unnecessary quantum dots is 0.454 ng, 0.872 ng. 0.498 ng, and 1.021 ng, respectively, corresponding to the auxiliary layer formed by the four materials: butylamine, amphetamine, N-β-(aminoethyl)-γ-aminopropyl methyl dimethoxysilane and tetraethylammonium chloride, so it can be concluded that the introducing of the above auxiliary layer obviously weakens the residual amount of unnecessary quantum dots, and the influence of residue of nanogram-level on the color crosstalk of quantum dot light emitting devices can be ignored.

It should also be noted that, quantum dot layers of various colors include quantum dots emitting light of different colors, which can be semiconductor nanocrystals and have various shapes, such as spherical, conical, multi-armed, and/or cubic nanoparticles, nanotubes, nanowires, nanofibers, nano-plate particles, quantum rods, or quantum sheets. Here, the quantum rod may be a quantum dot having an aspect ratio (ratio of length:diameter) (ratio of length:width) greater than about 1, for example, greater than or equal to about 2, greater than or equal to about 3, or greater than or equal to about 5. For example, the quantum rod may have an aspect ratio of less than or equal to about 50, less than or equal to about 30, or less than or equal to about 20.

For example, in an exemplary embodiment, the quantum dots 2031 may have a particle diameter (average maximum particle length for non spherical shapes) of, for example, about 1 nm to about 100 nm, about 1 nm to about 80 nm, about 1 nm to about 50 nm, or about 1 nm to 20 nm.

For example, the band gap of the quantum dots can be controlled according to their size and composition, and thus the emission wavelength can be controlled. For example, when the size of a quantum dot increases, the quantum dots may have a narrow band gap and thus may emit light in a relatively long wavelength region, while when the size of the quantum dot decreases, quantum dots may have a wide band gap and thus may emit light in a relatively short wavelength region. For example, quantum dots may be configured to emit light in a predetermined wavelength region in the visible region according to their size and/or composition. For example, the quantum dots may emit blue light, red light, or green light, and the blue light may have a peak emission wavelength (maximum λ) in, for example, about 430 nm to about 480 nm, the red light may have a peak emission wavelength (maximum λ) in, for example, about 600 nm to about 650 nm, and the green light may have a peak emission wavelength (maximum λ) in, for example, about 520 nm to about 560 nm.

For example, the average particle size of quantum dots that can emit blue light is, for example, less than or equal to about 4.5 nm, and, for example, less than or equal to about 4.3 nm, less than or equal to about 4.2 nm, less than or equal to about 4.1 nm, or less than or equal to about 4.0 nm. In this range, for example, the average particle size of the quantum dots may be about 2.0 nm to about 4.5 nm, such as about 2.0 nm to about 4.3 nm, about 2.0 nm to about 4.2 nm, about 2.0 nm to about 4.1 nm, or about 2.0 nm to about 4.0 nm.

For example, the quantum dots may have a relatively narrow half width (FWHM), which is a width of a wavelength corresponding to half of a peak absorption point, and when the FWHM is narrow, the quantum dots may be configured to emit light in a narrow wavelength region, and higher color purity may be obtained. The quantum dots may have an FWHM of, for example, less than or equal to about 50 nm. Within the above range, the quantum dots may have an FWHM of, for example, about 2 nm to about 49 nm.

For example, the material of the quantum dots may include a group II-VI semiconductor compound, a group III-V semiconductor compound, a group IV-VI semiconductor compound, a group I-III-VI semiconductor compound, a group I-II-IV-VI semiconductor compound, a group II-III-V semiconductor compound, or a combination of the above semiconductor compounds. The group II-VI semiconductor compound is selected from, for example, binary compounds such as a mixture of CdSe, CdTe, ZnS, ZnSe, ZnTe, ZnO, HgS, HgSe, HgTe, MgSe, MgS; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a mixture of the above compounds, or quaternary compounds such as HgZnTeS, CdZnSeS, CdZnSeTe, CdZnSTe, CdHgSeS, CdHgSeTe, CdHgSTe, HgZnSeS, HgZnSeTe, HgZnSTe, or a mixture of the above compounds, but embodiments of the present disclosure are not limited thereto. The group III-V semiconductor compound can be selected from a mixture of binary compounds such as a mixture of GaN, GaP, GaAs, GaSb, AlN, AIP, AlAs, AlSb, InN, InP, InAs, InSb; ternary compounds such as GaNP, GaNAs, GaNSb, GaPAs, GaPSb, AlNP, AlNAs, AlNSb, AlPAs, AlPSb, InNP, InNAs, InNSb, InPAs, InPSb, or a mixture of the above compounds; and quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a mixture of the above compounds, but embodiments of the present disclosure are not limited thereto. The group IV-VI semiconductor compound may be selected from, for example, binary compounds such as a mixture of SnS, SnSe, SnTe, PbS, PbSe, PbTe; ternary compounds such as SnSeS, SnSeTe, SnSTe, PbSeS, PbSeTe, PbSTe, SnPbS, SnPbSe, SnPbTe, or a mixture of the above compounds; and quaternary compounds such as SnPbSSe, SnPbSeTe, SnPbSTe, or a mixture of the above compounds, but embodiments of the present disclosure are not limited thereto. The group I-III-VI semiconductor compound may be, for example, CuInSe₂, CuInS₂, CuInGaSe, CuInGaS, or a mixture of the above compounds, but the embodiments of the present disclosure are not limited thereto. The group I-II-IV-VI semiconductor compound may be, for example, CuZnSnSe, CuZnSnS, or a mixture of the above compounds, but embodiments of the present disclosure are not limited thereto. The group II-III-V semiconductor compound may include, for example, InZnP, but embodiments of the present disclosure are not limited thereto.

For example, the quantum dots may have a substantially uniform concentration distribution or a locally different concentration distribution, and the quantum dots include a mixture of the above binary semiconductor compounds, the above ternary semiconductor compounds, or the above quaternary semiconductor compounds.

For example, as an embodiment, the quantum dots may be a Zn—Te—Se semiconductor compound. For example, the amount of tellurium (Te) in the Zn—Te—Se semiconductor compound may be smaller than the amount of selenium (Se) in the Zn—Te—Se semiconductor compound. The semiconductor compound may have a peak emission wavelength (maximum 2) in a wavelength region less than or equal to about 480 nm, for example, about 430 nm to about 480 nm, and may be configured to emit blue light.

For example, the quantum dots may be In—Zn—P semiconductor compound. For example, In the In—Zn—P semiconductor compound, the molar ratio of zinc (Zn) to indium (In) may be greater than or equal to about 25. The semiconductor compound may have a peak emission wavelength (maximum 2) in a wavelength region less than about 700 nm, for example, about 600 nm to about 650 nm, and may be configured to emit red light.

For example, the quantum dot may have a core-shell structure, that is, a nanoparticle formed by a layer of quantum dot material surrounding another quantum dot material. For example, there may be an interface between the core and the shell of a quantum dot, and at least one element of the core or the shell in the interface may have a concentration gradient, and the concentration of the element of the shell gradually decreases in a direction towards the core. For example, the material composition of the shell of the quantum dot has a higher energy band gap than that of the core of the quantum dot, and thus the quantum dot can exhibit a quantum confinement effect.

For example, the quantum dot may have a quantum dot core and multiple quantum dot shells surrounding the core. The multilayer shell refers to having at least two shells, each of the shells can be of a single composition, alloy, and/or a structure with a concentration gradient.

For example, the shell of the multilayer shell away from the core has a higher energy band gap than the shell of the multilayer shell close to the core, and thus the quantum dot can exhibit a quantum confinement effect.

For example, a quantum dot having a core-shell structure may, for example, include a core including a first semiconductor compound including at least one selected from the group consisting of zinc (Zn), tellurium (Te), and selenium (Se); and a shell including a second semiconductor compound arranged on at least a part of the core and having a composition different from that of the core.

For example, the first semiconductor compound may be a semiconductor compound including zinc (Zn), tellurium (Te) and selenium (Se), based on Zn—Te—Se semiconductor compound, for example, a semiconductor compound including a small amount of tellurium (Te) based on Zn—Se semiconductor compound, for example, a semiconductor compound represented by ZnTexSe(1−x), where x is greater than about 0 and less than or equal to 0.05.

For example, in the first semiconductor compound based on Zn—Te—Se, the molar amount of zinc (Zn) may be higher than that of selenium (Se), and the molar amount of selenium (Se) may be higher than that of tellurium (Te). For example, in the first semiconductor compound, the molar ratio of tellurium (Te) to selenium (Se) may be less than or equal to about 0.05. For example, in the first semiconductor compound, the molar ratio of tellurium (Te) to zinc (Zn) may be less than or equal to about 0.02.

For example, the second semiconductor compound may include a group II-VI semiconductor compound, a group III-V semiconductor compound, a group IV-VI semiconductor compound, a group IV semiconductor compound, a group I-III-VI semiconductor compound, a group I-II-IV-VI semiconductor compound, a group II-III-V semiconductor compound or a combination of the above compounds. Examples of the group II-VI semiconductor compound, group III-V semiconductor compound, group IV-VI semiconductor compound, group IV semiconductor, group I-III-VI semiconductor compound, group I-II-IV-VI semiconductor compound, and group II-III-V semiconductor compound are the same as those described above.

For example, the second semiconductor compound may include zinc (Zn), selenium (Sc), and/or sulfur(S). For example, the shell may include ZnSeS, ZnSe, ZnS, or a combination thereof. For example, the shell may include at least one inner shell arranged close to the core and an outermost shell arranged at the outermost side of the quantum dot. The inner shell may include ZnSeS, ZnSe or a combination of the above compounds, and the outermost shell may include ZnS. For example, the shell may have a concentration gradient of one component, and, for example, the amount of sulfur(S) may increase with increasing of a distance from the core.

For example, the core of a quantum dot having a core-shell structure includes a third semiconductor compound, which includes at least one selected from the group consisting of indium (In), zinc (Zn), and phosphorus (P); and a shell arranged on at least a part of the core and including a fourth semiconductor compound having a different composition from that of the core.

For example, in the third semiconductor compound based on In—Zn—P, the molar ratio of zinc (Zn) to indium (In) may be greater than or equal to about 25. For example, in the third semiconductor compound based on In—Zn—P, the molar ratio of zinc (Zn) to indium (In) may be greater than or equal to about 28, greater than or equal to about 29, or greater than or equal to about 30. For example, in the third semiconductor compound based on In—Zn—P, the molar ratio of zinc (Zn) to indium (In) may be less than or equal to about 55, for example, less than or equal to about 50, less than or equal to about 45, less than or equal to about 40, less than or equal to about 35, less than or equal to about 34, less than or equal to about 33, or less than or equal to about 32.

For example, the fourth semiconductor compound may include a group II-VI semiconductor compound, a group III-V semiconductor compound, a group IV-VI semiconductor compound, a group IV semiconductor compound, a group I-III-VI semiconductor compound, a group I-II-IV-VI semiconductor compound, a group II-III-V semiconductor compound or a combination of the above compounds. Examples of the group II-VI semiconductor compound, group III-V semiconductor compound, group IV-VI semiconductor compound, group IV semiconductor compound, group I-III-VI semiconductor compound, group I-II-IV-VI semiconductor compound, and group II-III-V semiconductor compound may be the same as those described above.

For example, the fourth semiconductor compound may include zinc (Zn), sulfur(S) or selenium (Se). For example, the shell may include ZnSeS, ZnSe, ZnS or a combination of the above compounds. For example, the shell may include at least one inner shell arranged close to the core and a shell arranged at the outermost side of the quantum dot. At least one of the inner shell and the outermost shell may include a fourth semiconductor compound that is ZnS, ZnSe, or ZnSeS.

For example, the quantum dot may have a relatively deep HOMO energy level, for example, the following HOMO energy level: greater than or equal to about 5.4 eV, within this range, for example greater than or equal to about 5.5 eV, for example greater than or equal to about 5.6 eV, for example greater than or equal to about 5.7 eV, for example greater than or equal to about 5.8 eV, for example greater than or equal to about 5.9 e V, for example greater than or equal to about 6.0 eV. Within this range, the HOMO energy level of the quantum dot layer may be, for example, about 5.4 eV to about 7.0 eV.

For example, the quantum dot may have a relatively shallow LUMO energy level, for example, less than or equal to about 3.7 eV, within this range, for example, less than or equal to about 3.6 eV, for example, less than or equal to about 3.5 eV, for example, less than or equal to about 3.4 eV, for example, less than or equal to about 3.3 eV, for example, less than or equal to about 3.2 eV, for example, less than or equal to about 3.0 eV. Within this range, the LUMO energy level of the quantum dot layer may be about 2.5 eV to about 3.7 eV, about 2.5 eV to about 3.6 eV, about 2.5 eV to about 3.5 eV, about 2.5 eV to about 3.4 eV, about 2.5 eV to about 3.3 eV, about 2.5 eV to about 3.2 eV, about 2.5 eV to about 3.1 eV, about 2.5 eV to about 3.0 eV, about 2.8 eV to about 3.7 eV, about 2.8 eV to about 3.6 eV, about 2.8 eV to about 3.5 eV, about 2.8 eV to about 3.4 eV, about 2.8 eV to about 3.3 eV, about 2.8 eV to about 3.2 eV, about 3.0 eV to about 3.7 eV, about 3.0 eV to about 3.6 eV, about 3.0 eV to about 3.5 eV, or about 3.0c V to about 3.4 eV.

For example, the quantum dot may have an energy band gap of about 1.7 eV to about 2.3 eV or about 2.4 eV to about 2.9 eV. Within this range, for example, the quantum dot layer 13 may have the following energy band gap: about 1.8 eV to about 2.2 eV or about 2.4 eV to about 2.8 eV, within this range, for example, about 1.9 eV to about 2.1 eV, for example, about 2.4 eV to about 2.7 eV.

For example, in an exemplary embodiment, the material of the quantum dot includes a quantum dot with a core-shell structure, in which a group IIB-VIA semiconductor compound is used as a core and a shell, respectively, and the materials of the core and the shell can be binary compounds, ternary compounds, or quaternary compounds, respectively. For example, the materials of the core and shell of the quantum dot can be CdSe, CdTe, ZnS, ZnSe, ZnTe, ZnO, HgS, HgSe, and HgTe, respectively.

For example, the material of the quantum dot includes at least two metals. The material of the quantum dot layer is at least one of CdSeS, CdSeTe, CdSTe, ZnSeS, ZnSeTe. ZnSTe, HgSeS, HgSeTe, HgSTe, CdZnS, CdZnSe, CdZnTe, CdHgS, CdHgSe, CdHgTe, HgZnS, HgZnSe, CdZnSeS, CdZnSeTe, CdZnSTe, CdHgSeS, CdHgSeTe, CdHgSTe, HgZnSeS, HgZnSeTe, and HgZnSTe. Usually, when a quantum dot is excited by a blue light source, it will emit excitation fluorescence with a specific wavelength, and its emitted fluorescence spectrum is determined by the chemical composition and particle size of the quantum dot material. With the increase of particle size, the fluorescence spectrum of quantum dot materials with the same chemical composition shifts from green light to red light. The adopted quantum dot materials emitting red light and green light can be quantum dot materials with the same chemical composition but different particle sizes, or they can be quantum dot materials with different chemical compositions, that is, the quantum dots in adjacent sub-pixel regions can be made of the same material but have different particle sizes, or the quantum dots in adjacent sub-pixel regions can be made of different materials.

For example, the quantum dot is a nano-scale semiconductor. By applying a certain electric field or light pressure to the nano-scale semiconductor material, the nano-scale semiconductor material will emit light with a specific frequency, and the frequency of the emitted light will change with the change of the size of the semiconductor, so the color of the emitted light can be controlled by adjusting the size of the quantum dot.

For example, by controlling the shape, structure and size of quantum dots, the electronic states of quantum dots, such as energy gap width, exciton binding energy, and exciton energy blue shift, can be easily adjusted. With the decrease of quantum dot size, the spectrum blue shift of quantum dot occurs. The smaller the size of quantum dots, the more obvious the blue shift phenomenon. For example, for CdSe quantum dots, when the size of the CdSe quantum dots being reduced from 10 nm to 2 nm, CdSe quantum dots emit light of the color from red to blue, and the CdSe quantum dots emit blue light in the case where CdSe quantum dots have a size greater than or equal to 2 nm and less than 5 nm; CdSe quantum dots emit green light in the case where CdSe quantum dots have a size greater than or equal to 5 nm and less than 8 nm; CdSe quantum dots emit red light in the case where CdSe quantum dots have a size greater than or equal to 8 nm and less than 10 nm.

For example, the unique properties of quantum dots are based on their own quantum size effect. When the particle size enters the nanometer scale, size confinement will cause size effect, quantum confinement effect, macroscopic quantum tunneling effect, and surface effect, thus deriving that nano-systems have different low-dimensional physical properties from micro-systems, which makes quantum dots have different physical and chemical properties from micro-systems. For example, quantum dots have unique photoluminescence and electroluminescence properties due to quantum size effect and electric confinement effect. Compared with organic fluorescent dyes, quantum dots have excellent optical characteristics, such as high quantum yield, high photochemical stability, difficult photolysis, wide excitation, narrow emission, high color purity, and the luminous color can be adjusted by controlling the size of quantum dots. In this way, quantum dot light-emitting devices including the quantum dot light-emitting layer have the advantages of high luminous efficiency, good stability, long life, high brightness, and wide color gamut.

For example, in an exemplary embodiment, the material of the auxiliary layer 202 includes nanoparticles with a metal element, which is the metal element contained in the surface of the quantum dot in contact with the first ligand.

For example, in another exemplary embodiment, the material of the auxiliary layer 202 includes nanoparticles with a nonmetallic element, which is the nonmetallic element contained in the surface of the quantum dot in contact with the first ligand.

For example, the nanoparticles occupy a site where unnecessary quantum dot materials may remain, and the state of the particles when being contacted with each other is more unstable, which makes it more difficult for unnecessary quantum dot materials that may be introduced later to remain at this site, so that the quantum dot materials remaining on the auxiliary layer 202 can be removed more easily.

For example, in an exemplary embodiment, the photoluminescence quantum yields of the nanoparticles with metal element and the nanoparticles with nonmetallic element are both less than 2%, so that the nanoparticles included in the auxiliary layer 202 do not emit light substantially.

For example, in an exemplary embodiment, the size of the nanoparticles with metal element and the size of the nanoparticles with non-metal element are both smaller than that of the quantum dots, so that the nanoparticles with metal element and the nanoparticles with non-metal element can be more dense relative to the quantum dots, that is, the gap between the nanoparticles with metal element and the gap between the nanoparticles with non-metal elements are smaller, so that the nanoparticles can occupy all sites where unnecessary quantum dot materials may remain.

For example, in another exemplary embodiment, the quantum dots 2031 each has a core-shell structure, the material of the shell of the quantum dot 2031 and the material of the core of the quantum dot 2031 include at least the same element, and the material of the auxiliary layer 202 is the same as that of the core of the quantum dot 2031. For example, the material of the core of the quantum dot 2031 can be a nanoparticle, and the material of the auxiliary layer 202 can also be a nanoparticle, so that the quantum dot material remaining on the auxiliary layer 202 can be removed more easily, so as to reduce the risk of color mixing caused by unnecessary quantum dot residue and improve the color gamut of the subsequently formed quantum dot light-emitting device.

It should be noted that in the case where the material of the auxiliary layer is the same as that of the core of the quantum dot, the material of the auxiliary layer does not have the quantum confinement effect of the shell, but only plays the role of transporting electrons and does not have the function of emitting light. For example, the auxiliary layer can be formed by spin-coating and soaking the material including the cores of quantum dots, and the molar concentration of the material of the cores of quantum dots in the solution is 0.001 g/L or less. The auxiliary layer formed by using this material can be discontinuous, and the material of the shell of quantum dot and the material of the core of quantum dot at least include the same element, so that the material of the auxiliary layer and the material of the shell of quantum dot also include the same element, so as to reduce the color-crosstalk problem caused by the residue of quantum dots.

For example, in an exemplary embodiment, the material of the auxiliary layer 202 includes the material of nanoparticles contained in the core of the quantum dot 2031, and the size of the nanoparticles is the same or basically the same as that of the cores of the quantum dots, which makes it easier to select the material of the auxiliary layer 202, and the shape of the nanoparticles makes it easier to remove unnecessary quantum dots remaining thereon, thereby reducing or eliminating unnecessary quantum dot residues.

For example, in an exemplary embodiment, the material of the cores of the quantum dots 2031 includes at least one selected from the group consisting of CdS, CdSe, InP, and PbS, and the material of the shells of the quantum dots 2031 includes an other material except that selected as the core. For example, the material of the cores of the quantum dots 2031 is CdS, and the material of the shells of the quantum dots 2031 is PbS, the material of the core and the material of the shell contain the same elemental sulfur, and the compound containing metal element or nonmetallic element includes at least one selected from the group consisting of CdS and PbS.

For example, in another exemplary embodiment, the material of the quantum dot includes compounds formed by various metal cations and anions. For example, the material of the quantum dot includes compounds formed by two metal elements and one nonmetallic element. The material of the auxiliary layer 202 is a compound containing a metal element, and the compound containing a metal element at least includes at least one selected from the group consisting of the metal cations, so that the material of the auxiliary layer is similar to that of the outer surface of the quantum dot, so that the auxiliary layer firstly occupies a site where unnecessary quantum dot material may remain.

For example, in an exemplary embodiment, the material of the quantum dot includes a compound formed by a plurality of metal cations and anions, and the material of the auxiliary layer 202 is a compound containing a nonmetallic element, and the compound containing the nonmetallic element includes the anion, so that the material of the auxiliary layer can be made similar to that of the outer surface of the quantum dot, so that the auxiliary layer firstly occupies a site where unnecessary quantum dot material may remain.

For example, in an exemplary embodiment, the compound containing a metal element or the compound containing a nonmetallic element includes at least one selected from the group consisting of CsPbCl₃, CsPbBr₃ and CsPbI₃.

For example, in an exemplary embodiment, the material of the quantum dot includes CsPbCl₃, that is, the material of the quantum dot includes two metal elements, Cs and Pb, and the non-metallic element, Cl, and the material of the auxiliary layer 202 is a compound containing metal elements, which includes at least one selected from the group consisting of Cs and Pb. The compound containing a nonmetallic element includes Cl element.

For example, in another exemplary embodiment, the material of the auxiliary layer 202 includes a compound containing a second functional group and a compound containing a metal element, which are dissolved in ethanol, and the ratio of the molar concentration of the compound containing a second functional group to the molar concentration of the compound containing a metal element is in a range from 10:1 to 30:1, for example, the ratio of the molar concentration is 10:1, 12:1, 15:1, 18:1, 20:1, 24:1, 27:1, or 30:1. The compound containing the second functional group included in the material of the auxiliary layer 202 can reduce the interaction between the auxiliary layer 202 and the first ligand on the surface of quantum dots in the quantum dot light-emitting layer 2031, so that unnecessary quantum dots are not easy to remain. The compound containing the metal element included in the material of the auxiliary layer 202 can reduce the interaction between the auxiliary layer 202 and the quantum dots in the quantum dot light-emitting layer 2031, so that the binding ability between the residual quantum dots themselves and the auxiliary layer 202 is weaker, and unnecessary quantum dots are less likely to remain on the auxiliary layer 202.

For example, in an exemplary embodiment, the material of the auxiliary layer 202 includes a compound containing a second functional group and a compound containing a nonmetallic element, and the ratio of the molar concentration of the compound containing a second functional group to the molar concentration of the compound containing a nonmetallic element is in a range from 10:1 to 30:1, for example, the ratio of the molar concentration is 10:1, 12:1, 15:1, 18:1, 20:1, 24:1, 27:1, or 30:1. The compound containing the second functional group included in the material of the auxiliary layer 202 can reduce the interaction between the auxiliary layer 202 and the first ligand on the surface of quantum dots in the quantum dot light-emitting layer 2031, so that the residual quantum dots can be removed more easily. The compound containing the nonmetallic element included in the material of the auxiliary layer 202 can reduce the interaction between the auxiliary layer 202 and the quantum dots in the quantum dot light-emitting layer 2031, so that the binding ability between the residual quantum dots themselves and the auxiliary layer 202 is weaker, and the residual quantum dots can be removed more easily.

For example, the auxiliary layer 202 may be continuous or discontinuous, and in the case where the auxiliary layer 202 is discontinuous, the auxiliary layer 202 corresponds to the region where the quantum dot layer that is later formed is located. For example, in an exemplary embodiment, if the red quantum dot layer is formed first, then the green quantum dot layer is formed, and finally the blue quantum dot layer is formed, the auxiliary layer 202 is not formed in the region corresponding to the red quantum dot layer, but is formed in the region corresponding to the green quantum dot layer and the blue quantum dot layer, so as to reduce the coverage area of the auxiliary layer 202, thereby reducing the manufacturing cost of the auxiliary layer 202.

For example, in an exemplary embodiment, the thickness of the auxiliary layer 202 is 1 nm to 5 nm, for example, the thickness of the auxiliary layer 202 is 1 nm, 2 nm, 3 nm, 4 nm or 5 nm. The auxiliary layer within this thickness range can not only reduce or eliminate unnecessary quantum dot residues, but also ensure good electron transport performance, and the auxiliary layer 202 within this thickness range can also simplify the preparation process and reduce the cost. In the case where the thickness of the auxiliary layer 202 is greater than 5 nm, the electron transport performance of the whole quantum dot light-emitting device will be reduced, and in the case where the thickness of the auxiliary layer 202 is less than 1 nm, the occupying effect will be affected because of its too thin thickness, and the problem of unnecessary quantum dot residue cannot be reduced or eliminated.

For example, the electron transport layer 201 may include inorganic nanoparticles or an inorganic layer. The inorganic nanoparticles may be, for example, oxide nanoparticles, and may be, for example, metal oxide nanoparticles.

For example, the inorganic nanoparticles may be two-dimensional or three-dimensional nanoparticles with the following average particle diameters: less than or equal to about 10 nm, less than or equal to about 8 nm, less than or equal to about 7 nm, less than or equal to about 5 nm, less than or equal to about 4 nm, less than or equal to about 3.5 nm, or the size of the inorganic nanoparticles is about 1 nm to about 10 nm, about 1 nm to about 9 nm, about 1 nm to about 8 nm, about 1 nm to about 7 nm, about 1 nm to about 5 nm, about 1 nm to about 4 nm, or about 1 nm to about 3.5 nm.

For example, the inorganic nanoparticles may be metal oxide nanoparticles, which include oxides formed by at least one selected from the group consisting of zinc (Zn), magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), and barium (Ba).

For example, the first inorganic nanoparticles may include metal oxide nanoparticles containing zinc (Zn) and may include metal oxide nanoparticles represented by Zn₁₋ₓQxO(0≤x<0.5). For example, Q is at least one metal different from Zn, such as at least one selected from the group consisting of magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), silicon (Si), and barium (Ba).

For example, Q may include magnesium (Mg).

For example, the value range of x can be further 0.005≤x≤0.25, or further 0.01≤x≤0.2.

For example, the material of the inorganic layer is a metal oxide, which includes a metal oxide formed by at least one selected from the group consisting of the following: zinc (Zn), magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), and barium (Ba).

For example, in an exemplary embodiment, the material of the electron transport layer 201 includes at least one selected from the group consisting of zinc oxide, zinc oxide doped with magnesium ions and zinc oxide doped with cesium ions.

For example, in an exemplary embodiment, the material of the electron transport layer 201 includes 4,7-diphenyl-1,10-o-phenanthroline (BPhen), 1,3,5-tris(1-phenyl-1H-benzimidazole-2-yl)benzene (TPBI) and N-doping electron transport material, but is not limited thereto. The n-doping electron transport material includes, for example, 2,9-dimethyl-4,7-biphenyl-1.10-o-phenanthroline (BCP): Li₂CO₃, 8-hydroxyquinoline aluminum (Alq₃): Mg. TPBI: Li, etc., but the embodiments of the present disclosure are not limited to this.

For example, FIG. 4 is a schematic cross-sectional structural view of yet another quantum dot light-emitting device provided by at least one embodiment of the present disclosure. As illustrated in FIG. 4, in the quantum dot light-emitting device 200, three sub-pixel regions 2041 are illustrated, and the quantum dot light-emitting layer 203 includes a first color quantum dot layer 203a, a second color quantum dot layer 203b, and a third color quantum dot layer 203c. The first color quantum dot layer 203a is arranged in the first sub-pixel region 2041a, the second color quantum dot layer 203b is arranged in the second sub-pixel region 2041b, and the third color quantum dot layer 203c is arranged in the third sub-pixel region 2041c. For example, the first color quantum dot layer 203a may include red quantum dots, the second color quantum dot layer 203b may include green quantum dots, and the third color quantum dot layer 203c may include blue quantum dots, so that the red light emitted from the first color quantum dot layer 203a, the green light emitted from the second color quantum dot layer 203b, and the blue light emitted from the third color quantum dot layer 203c can be mixed to form white light. Therefore, the quantum dot light-emitting device can have good display color. The materials of the red quantum dots, the green quantum dots, and the blue quantum dots are not particularly limited, and those skilled in the art can choose according to the commonly used materials of the red quantum dots, the green quantum dots and the blue quantum dots. The following is an example of forming the first color quantum dot layer 203a first, then the second color quantum dot layer 203b, and finally the third color quantum dot layer 203c.

For example, in the structure illustrated in FIG. 4, because the auxiliary layer 202 is provided between the electron transport layer 201 and the quantum dot light-emitting layer 203, there is no red quantum dot residue in the second sub-pixel region 2041b and no red quantum dot residue and green quantum dot residue in the third sub-pixel region 2041c, there is no problem of color mixing, so that the color gamut of the quantum dot light-emitting device can be improved.

For example, in FIG. 4, the material of the red quantum dots, the material of the green quantum dots and the material of the blue quantum dots may be the same, and the ligands on the surfaces of quantum dots emitting light of different colors are the same, but the sizes of the quantum dots of different colors are different. In this case, the materials of the auxiliary layers corresponding to respective sub-pixel regions are the same.

It should be noted that, in the case where the materials of the first color quantum dots 2031a in the first color quantum dot layer 203a, the second color quantum dots 2031b in the second color quantum dot layer 203b, and the third color quantum dots 2031c in the third color quantum dot layer 203c are different, and the functional groups on the surfaces of the corresponding first color quantum dots 2031a, the corresponding second color quantum dots 2031b, and the corresponding third color quantum dots 2031c are different, the materials of the subsequent auxiliary layers corresponding to different color quantum dot layers 203 can be made different, that is, the material of the auxiliary layer corresponding to the first color quantum dots 2031a includes a compound formed by a metal element and a nonmetallic element that are included in the first color quantum dots 2031a, or the material of the auxiliary layer corresponding to the first color quantum dots 2031a includes the second functional group of the first ligand on the surface of the first color quantum dots 2031a that is not in contact with the first color quantum dots 2031a; the material of the auxiliary layer corresponding to the second color quantum dots 2031b includes a compound formed by a metal element and a nonmetallic element that are included in the second color quantum dots 2031b, or the material of the auxiliary layer corresponding to the second color quantum dots 2031b includes a second functional group of the first ligand on the surface of the second color quantum dots 2031b that is not in contact with the second color quantum dots 2031b; the material of the auxiliary layer corresponding to the third color quantum dots 2031c includes a compound of a metal element and a nonmetallic element that are included in the third color quantum dots 2031c, or the material of the auxiliary layer corresponding to the third color quantum dots 2031c includes a second functional group of the first ligand on the surface of the third color quantum dots 2031c that is not in contact with the third color quantum dots 2031c. That is, the auxiliary layer 202 is discontinuous and has different materials in regions corresponding to adjacent sub-pixel regions 2041.

For example, FIG. 5 is a schematic cross-sectional structural view of still another quantum dot light-emitting device provided by at least one embodiment of the present disclosure. As illustrated in FIG. 5, the quantum dot light-emitting device 200 further includes a base substrate 210, a first electrode 214, an electron transport layer 201, and an auxiliary layer 202 that are stacked on the base substrate 210, and the first electrode 214 is arranged at a side of the electron transport layer 201 close to the base substrate 201. The electron transport layer 201, the first electrode 214, and the auxiliary layer 202 are all stacked in a plurality of sub-pixel regions 2041, that is, the electron transport layer 201, the first electrode 214, and the auxiliary layer 202 are all discontinuous.

For example, as illustrated in FIG. 5, the quantum dot light-emitting device 200 further includes a hole transport layer 211 and a hole injection layer 212 which are arranged in a plurality of sub-pixel regions 2041 and are arranged at the side of the first color quantum dot layer 203a, the second color quantum dot layer 203b, and the third color quantum dot layer 203c away from the base substrate 210, and the hole injection layer 212 is at the side of the hole transport layer 211 away from the base substrate 210. In different sub-pixel regions 2041, the stacked structures of the hole transport layer 211 and the hole injection layer 212 are spaced apart from each other. A second electrode 213 is arranged at the side of the hole injection layer 212 away from the base substrate 210, and the second electrode 213 is arranged on the whole surface, that is, the second electrodes 213 in different sub-pixel regions 2041 are connected to each other.

For example, the material of the hole transport layer include any one of N,N′-bis(1-naphthyl)-N,N′-diphenyl-1,1′-diphenyl-4,4′-diamine (NPB), 4,4′,4″-tris(N-3-methylphenyl-N-phenylamino)triphenylamine (m-MTDATA) and 4,4-2-[N-(4-carbazolylphenyl)-N-phenylamino]biphenyl (CPB).

For example, the hole injection layer can adopt a metal oxide MeO, such as MoO3, or a p-doped MeO (metal oxide)-TPD (N,N′10-bis(3-methylphenyl)-N,N′-diphenyl-1,1′-diphenyl-4,4′-diamine: F4TCNQ (N,N,N′,N′-tetramethoxyphenyl)-p-diaminobiphenyl: 2,3,5,6-tetrafluoro-7,7′,8,8′-tetracyanomethyl-p-benzoquinone), or M-MTDATA: F4TCNQ ((4,4′,4′-tri (N-3-methylphenyl-N-phenylamino)triphenylamine: 2,3,5,6-tetrafluoro-7,7′,8,8′-tetracyanomethyl-p-benzoquinone), etc.

For example, the material of the first electrode 214 may be a transparent conductive material, which includes indium tin oxide (ITO), indium zinc oxide (IZO), indium gallium oxide (IGO), gallium zinc oxide (GZO), zinc oxide (ZnO), indium oxide (In₂O₃), zinc aluminum oxide (AZO), carbon nanotubes and the like.

For example, the material of the second electrode 212 includes single metal of magnesium, aluminum, lithium or magnesium aluminum alloy (MgAl), lithium aluminum alloy (LiAl) and the like.

For example, the first electrode 214 is an anode and the second electrode 212 is a cathode.

It should be noted that, the above-mentioned materials and structures of the first electrode 214 and the second electrode 212 are only an example in the embodiment of the present disclosure. The first electrode and the second electrode can also be made of other materials, which can be divided into single-sided light-emitting quantum dot devices and double-sided light-emitting quantum dot devices according to the different materials of the first electrode and the second electrode. In the case where one of the anode and the cathode is opaque or semi-transparent, it is a single-sided light-emitting quantum dot device, and in the case where both of the anode and the cathode is transparent or semi-transparent, it is a double-sided light-emitting quantum dot device.

According to needs, the materials of the first electrode and the second electrode can be selected to be suitable for top light-emitting type, bottom light-emitting type, and double-sided light-emitting type, respectively. The embodiment of the present disclosure does not limit the selection of the materials of the first electrode and the second electrode.

For example, in FIG. 5, the related features of the first color quantum dot layer 203a, the second color quantum dot layer 203b, the third color quantum dot layer 203c, and the auxiliary layer 202 can be referred to the above-mentioned related descriptions, which are not repeated herein.

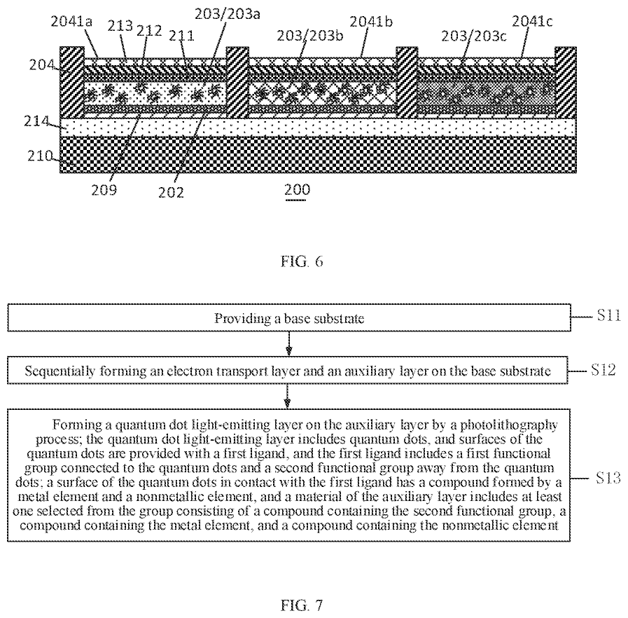

For example, FIG. 6 is a schematic cross-sectional structural view of still another quantum dot light-emitting device provided by at least one embodiment of the present disclosure. As illustrated in FIG. 6, the quantum dot light-emitting device 200 further includes an electron injection layer 209 arranged between the first electrode 214 and the electron transport layer 202, and the first electrode 214 is formed on the whole surface. The second electrodes 213 in different sub-pixel regions 2041 are spaced apart from each other, so that the first color quantum dot layer 203a in the first sub-pixel region 2041a can emit light of a first color, the second color quantum dot layer 203b in the second sub-pixel region 2041b can emit light of a second color, and the third color quantum dot layer 203c in the third sub-pixel region 2041c can emit light of a third color. The light of the first color, the light of the second color, and the light of the third color have different colors, so that the purity of the light emitted from respective sub-pixel regions 2041 is higher.

For example, in FIG. 6, the related features of the first color quantum dot layer 203a, the second color quantum dot layer 203b, the third color quantum dot layer 203c, and the auxiliary layer 202 can be referred to the above-mentioned related descriptions, which are not repeated herein.

For example, the material of the electron injection layer 209 includes lithium oxide (Li₂O), cesium oxide (Cs₂O), sodium oxide (Na₂O), lithium carbonate (Li₂CO₃), cesium carbonate (Cs₂CO₃), or sodium carbonate (Na₂CO₃), lithium fluoride (LiF), cesium fluoride (CsF), sodium fluoride (NaF), calcium fluoride (CaF₂), 8-hydroxyquinoline lithium (Liq), 8-hydroxyquinoline gallium, bis [2-(2-hydroxyphenyl-1)-pyridine]beryllium, 2-(4-diphenyl)-5-(4-tert-butylphenyl)-1,3,4-oxadiazole (PBD).

For example, the materials of the electron transport layer, the hole transport layer, the hole injection layer, the first electrode, and the second electrode are not particularly limited. Please refer to the related description in FIG. 5 mentioned above, and those skilled in the art can choose according to the common materials of the above-mentioned structure of the quantum dot light-emitting device.

At least one embodiment of the present disclosure further provides a manufacturing method of a quantum dot light-emitting device, which includes: providing a base substrate; sequentially forming an electron transport layer and an auxiliary layer on the base substrate, and forming a quantum dot light-emitting layer on the auxiliary layer by a photolithography process; the quantum dot light-emitting layer includes quantum dots, and surfaces of the quantum dots are provided with a first ligand, and the first ligand includes a first functional group connected to the quantum dots and a second functional group away from the quantum dots; the surface of the quantum dots in contact with the first ligand is provided with a compound formed by a metal element and a nonmetallic element, and a material of the auxiliary layer includes at least one selected from the group consisting of a compound containing the second functional group, a compound containing the metal element, and a compound containing the nonmetallic element. The quantum dot light-emitting device prepared by the method can easily clean the quantum dot material which is formed on the auxiliary layer and does not receive illumination, thereby reducing the color mixing phenomenon of the subsequently formed quantum dot light-emitting device and improving the color gamut of the subsequently formed quantum dot light-emitting device.

For example, FIG. 7 is a flowchart of a manufacturing method of a quantum dot light-emitting device provided by at least one embodiment of the present disclosure. As illustrated in FIG. 7, the manufacturing method includes the following steps.
S11: Providing a base substrate.
S12: Sequentially forming an electron transport layer and an auxiliary layer on the base substrate.
S13: Forming a quantum dot light-emitting layer on the auxiliary layer by a photolithography process; the quantum dot light-emitting layer includes quantum dots, and surfaces of the quantum dots are provided with a first ligand, and the first ligand includes a first functional group connected to the quantum dots and a second functional group away from the quantum dots; a surface of the quantum dots in contact with the first ligand has a compound formed by a metal element and a nonmetallic element, and a material of the auxiliary layer includes at least one selected from the group consisting of a compound containing the second functional group, a compound containing the metal element, and a compound containing the nonmetallic element.

For example, the base substrate includes a transparent insulating base substrate such as a glass base substrate and a flexible base substrate, and the material of the base substrate can be other suitable materials, which is not limited by the embodiment of the present disclosure.

For example, the material of the electron transport layer and the material of the auxiliary layer can be referred to the relevant descriptions above, and will not be repeated herein.

For example, in an exemplary embodiment, forming an electron transport layer includes: applying an ethanol solution including ZnMgO nanoparticles or ZnO nanoparticles on a base substrate; baking at 80° C.˜100° C. for 8 min˜12 min to form an electron transport layer with a thickness of 50 nm˜70 nm.

For example, the ethanol solution including ZnMgO nanoparticles or ZnO nanoparticles applied on the base substrate may be an ethanol solution of ZnMgO nanoparticles of 30 mg/mL or an ethanol solution of ZnO nanoparticles of 30 mg/mL by spin-coating at a rotation speed of 3000 rpm.

For example, in an exemplary embodiment, forming the electron transport layer includes: applying an ethanol solution including ZnMgO nanoparticles on the base substrate and baking at 90° C. for 10 min to form the electron transport layer.

For example, in an exemplary embodiment, forming the electron transport layer includes: applying an ethanol solution including ZnO nanoparticles on the base substrate and baking at a temperature of 85° C. for 11 min to form the electron transport layer.

For example, in an exemplary embodiment, forming the electron transport layer includes: applying an ethanol solution including ZnO nanoparticles on the base substrate and baking at 100° C. for 8 min to form the electron transport layer.

For example, in an exemplary embodiment, the thickness of the quantum dot light-emitting layer is 15 nm˜45 nm, for example, 15 nm, 20 nm, 25 nm, 30 nm, 35 nm, 40 nm or 45 nm.

For example, the surfaces of the quantum dots have the first ligand, which includes a first functional group connected to the quantum dots and a second functional group away from the quantum dots. The second functional group is an amino group, and the compound containing the second functional group include compounds of alkyl fatty amines with less than 7 carbon atoms, compounds of aromatic amines with electron transport properties, compounds of aminosilane coupling agents and compounds of quaternary ammonium salts.

For example, the compounds of alkyl fatty amines with less than 7 carbon atoms include at least one selected from the group consisting of ethylamine, propylamine and butylamine. The compounds of aromatic amines with electron transport properties include at least one selected from the group consisting of aniline, phenylethylamine and amphetamine. The compounds of aminosilane coupling agents include N-β-(aminoethyl)-γ-aminopropyl methyl dimethoxysilane. The compounds of quaternary ammonium include at least one selected from the group consisting of tetramethylammonium chloride and tetraethylammonium chloride.

For example, the first ligand is formed by the reaction of a second ligand under ultraviolet irradiation, and the structural formula of the first ligand includes

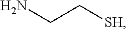

and the structural formula of the second ligand includes

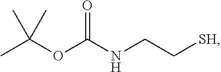

in the presence of an acid generator, the reaction formula of the second ligand forming the first ligand under ultraviolet irradiation is:

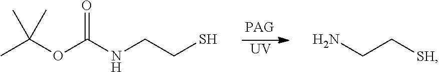

where PAG is an acid generator, and its structure is

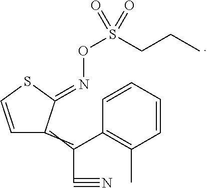 [SMILES: CCCS(=O)(=O)O/N=C1\SC=CC1=C(C#N)c1ccccc1C]

For example, in an exemplary embodiment, forming the auxiliary layer includes: applying an ethanol solution of a compound containing an amino group with a molar concentration of 0.01 mol/L to 0.05 mol/L on the electron transport layer, and then drying to form the auxiliary layer.

For example, in an exemplary embodiment, forming the auxiliary layer includes: applying an ethanol solution of ethylamine with a molar concentration of 0.04 mol/L on the electron transport layer, and then drying to form the auxiliary layer, which may be a continuous whole-layer structure or a discontinuous structure.

For example, in an exemplary embodiment, forming the auxiliary layer includes: applying an ethanol solution of amphetamine with a molar concentration of 0.02 mol/L on the electron transport layer, and then drying to form the auxiliary layer, which may be a continuous whole-layer structure or a discontinuous structure.

For example, in an exemplary embodiment, forming the auxiliary layer includes: applying an ethanol solution of N-β-(aminoethyl)-γ-aminopropyl methyl dimethoxysilane with a molar concentration of 0.03 mol/L on the electron transport layer, and then drying to form the auxiliary layer, which may be a continuous whole-layer structure or a discontinuous structure.

For example, in an exemplary embodiment, forming the auxiliary layer includes: applying an ethanol solution of tetramethylammonium chloride with a molar concentration of 0.05 mol/L on the electron transport layer, and then drying to form the auxiliary layer, which may be a continuous whole-layer structure or a discontinuous structure.

For example, the material of the auxiliary layer on the electron transport layer may be applied by spin-coating.

It should be noted that, in the case where the material of the first color quantum dots 2031a in the first color quantum dot layer 203a, the material of the second color quantum dots 2031b in the second color quantum dot layer 203b, and the material of the third color quantum dots 2031c in the third color quantum dot layer 203c are different, and the functional groups on the surfaces of the corresponding first color quantum dots 2031a, the second color quantum dots 2031b, and the third color quantum dots 2031c are different, the materials of the subsequent auxiliary layers corresponding to different color quantum dot layers 203 can be made different, that is, the material of the auxiliary layer corresponding to the first color quantum dots 2031a includes a compound formed by a metal element and a nonmetallic element that are included in the first color quantum dots 2031a, or the material of the auxiliary layer corresponding to the first color quantum dots 2031a includes the second functional group of the first ligand on the surface of the first color quantum dots 2031a that is not in contact with the first color quantum dots 2031a; the material of the auxiliary layer corresponding to the second color quantum dots 2031b includes a compound formed by a metal element and a nonmetallic element that are included in the second color quantum dots 2031b, or the material of the auxiliary layer corresponding to the second color quantum dots 2031b includes the second functional group of the first ligand on the surface of the second color quantum dots 2031b that is not in contact with the second color quantum dots 2031b; the material of the auxiliary layer corresponding to the third color quantum dots 2031c includes a compound of a metal element and a nonmetallic element that are included in the third color quantum dots 2031c, or the material of the auxiliary layer corresponding to the third color quantum dots 2031c includes the second functional group of the first ligand on the surface of the third color quantum dots 2031c that is not in contact with the third color quantum dots 2031c, that is, the auxiliary layer 202 is discontinuous and has different materials in regions corresponding to adjacent sub-pixel regions 2041.

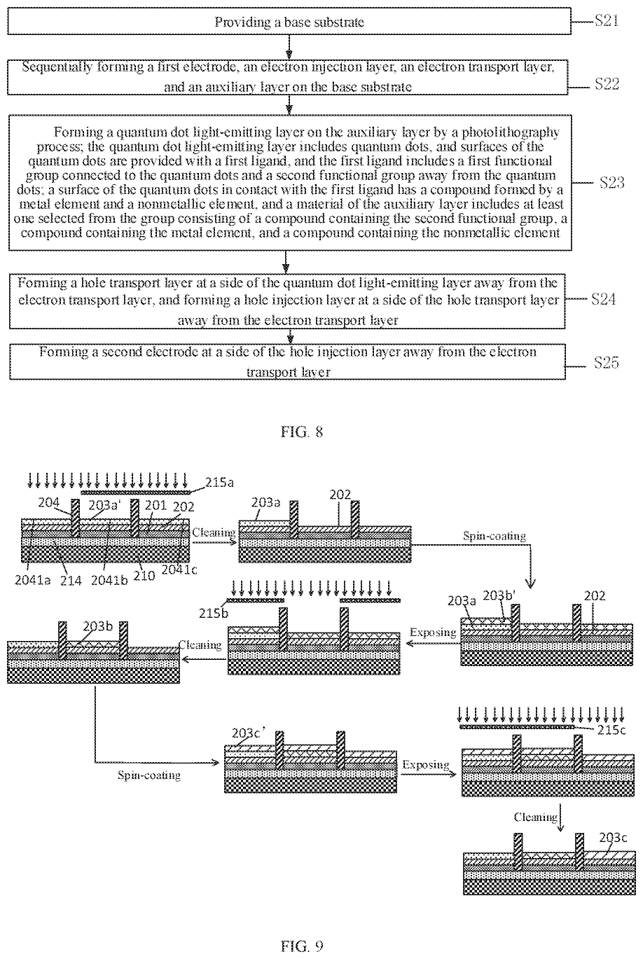

For example, FIG. 8 is a flowchart of another manufacturing method of a quantum dot light-emitting device provided by at least one embodiment of the present disclosure. As illustrated in FIG. 8, the method manufacturing method of the quantum dot light-emitting device includes the following steps.
S21: Providing a base substrate.
S22: Sequentially forming a first electrode, an electron injection layer, an electron transport layer, and an auxiliary layer on the base substrate.
S23: Forming a quantum dot light-emitting layer on the auxiliary layer by a photolithography process; the quantum dot light-emitting layer includes quantum dots, and surfaces of the quantum dots are provided with a first ligand, and the first ligand includes a first functional group connected to the quantum dots and a second functional group away from the quantum dots; a surface of the quantum dots in contact with the first ligand has a compound formed by a metal element and a nonmetallic element, and a material of the auxiliary layer includes at least one selected from the group consisting of a compound containing the second functional group, a compound containing the metal element, and a compound containing the nonmetallic element.
S24: Forming a hole transport layer at a side of the quantum dot light-emitting layer away from the electron transport layer, and forming a hole injection layer at a side of the hole transport layer away from the electron transport layer.
S25: Forming a second electrode at a side of the hole injection layer away from the electron transport layer.

For example, the related materials and structural features of the above-mentioned layer structure can be referred to the above-mentioned related descriptions, which are not limited by the embodiment of the present disclosure.

For example, in an exemplary embodiment, the quantum dots in the quantum dot light-emitting layer are made of zinc sulfide, and the materials of the auxiliary layer and the electron transport layer are both zinc oxide, and the thickness of the electron transport layer is 3 to 6 times that of the auxiliary layer in the direction perpendicular to the main surface of the base substrate, for example, the thickness of the electron transport layer is 3 times, 3.2 times, 3.8 times, 4 times, 4.8 times, 5 times, 5.2 times, 5.8 times, or 6 times that of the auxiliary layer.

For example, forming the first color quantum dot layer on the auxiliary layer by a photolithography process may include: applying a material of the first color quantum dot layer in a plurality of sub-pixel regions to form a first color quantum dot film, and then patterning the first color quantum dot film to form the first color quantum dot layer.

For example, patterning the first color quantum dot film includes: shielding an unexposed area of the first color quantum dot film with a mask plate, for example, shielding the second sub-pixel region and the third sub-pixel region, and exposing an area to be exposed (the first sub-pixel region) to crosslink a material of the first color quantum dots in the first sub-pixel region, and completing a development process, and removing a material of the first color quantum dot layer in the second sub-pixel region and the third sub-pixel region, thus forming a patterned first color quantum dot layer.

For example, the first color quantum dot layer includes the material of the first color quantum dots, and the thickening agent, coupling agent and accelerator included in the first color quantum dot layer can be referred to the above-mentioned related descriptions, which are not repeated here.

For example, a second color quantum dot layer and a third color quantum dot layer can be formed in the second sub-pixel region and the third sub-pixel region, respectively, and both the second color quantum dot layer and the third color quantum dot layer are formed by a photolithography process.

For example, the auxiliary layer may firstly occupy the sites where unnecessary quantum dots may remain, so as to reduce the problem of color-crosstalk caused by quantum dot residues and improve the color gamut of quantum dot light-emitting device.

For example, FIG. 9 is a schematic diagram of the manufacturing process of a quantum dot light-emitting device provided by at least one embodiment of the present disclosure. As illustrated in FIG. 9, providing a base substrate 210 with a first electrode 214 formed thereon, forming a pixel defining layer 204 on the first electrode 214, the pixel defining layer 204 including a plurality of openings to form a first sub-pixel region 2041a, a second sub-pixel region 2041b, and a third sub-pixel region 2041c which are spaced apart from each other; forming an electron transport layer 201, an auxiliary layer 202, and a material 203a′ of the first color quantum dot layer in the first sub-pixel region 2041a, the second sub-pixel region 2041b, and the third sub-pixel region 2041c, and shielding the second sub-pixel region 2041b and the third sub-pixel region 2041c by the first mask plate 215a so that light is irradiated to the first sub-pixel region 2041a and the material 203a′ of the first color quantum dot layer in the first sub-pixel region 2041a undergoes a cross-linking reaction, and completing the exposure process of the material 203a′ of the first color quantum dot layer in the first sub-pixel region 2041a, and cleaning the material 203a′ of the first color quantum dot layer in the second sub-pixel region 2041b and the third sub-pixel region 2041c to remove the material 203a′ located in the second sub-pixel region 2041b and the third sub-pixel region 2041c, and forming the first color quantum dot layer 203; spin-coating a material 203b′ of the second color quantum dot layer in the first sub-pixel region 2041a, the second sub-pixel region 2041b, and the third sub-pixel region 2041c, and the process of patterning the material 203b′ of the second color quantum dot layer includes: shielding the first sub-pixel region 2041a and the third sub-pixel region 2041c with a second mask plate 215b, so that light is irradiated to the second sub-pixel region 2041c so that the material 203b′ of the second color quantum dot layer in the second sub-pixel region 2041b undergoes a cross-linking reaction, completing the exposure process of the material 203b′ of the second color quantum dot layer, and cleaning the materials 203b′ of the second color quantum dot layer in the first sub-pixel region 2041a and the third sub-pixel region 2041c to remove the material located in the first sub-pixel region 2041a and the third sub-pixel region 2041c, and forming the second color quantum dot layer 203b; spin-coating a material 203c′ of the third color quantum dot layer in the first sub-pixel region 2041a, the second sub-pixel region 2041b, and the third sub-pixel region 2041c, the process of patterning the material 203c′ of the third color quantum dot layer includes: shielding the first sub-pixel region 2041a and the second sub-pixel region 2041b with a third mask plate 215c, so that light is irradiated to the third sub-pixel region 2041a and the material 203c′ of the third color quantum dot layer in the third sub-pixel region 2041c has a cross-linking reaction, completing the exposure process of the material 203c′ of the third color quantum dot layer, cleaning the material 203c′ of the third color quantum dot layer remaining in the first sub-pixel region 2041a and the second sub-pixel region 2041b to remove the material located in the first sub-pixel region 2041a and the second sub-pixel region 2041b, forming the third color quantum dot layer 203c.

It should be noted that, although not illustrated in FIG. 9, the material 203a′ of the first color quantum dot layer, the material 203b′ of the second color quantum dot layer, and the material 203c′ of the third color quantum dot layer are also formed on the pixel defining layer 204, and the material 203a′ of the first color quantum dot layer, the material 203b′ of the second color quantum dot layer, and the material 203c′ of the third color quantum dot layer on the pixel defining layer 204 are wash away in the cleaning process.

For example, in an exemplary embodiment, the first color quantum dot layer 203a, the second color quantum dot layer 203b, and the third color quantum dot layer 203c may be a red quantum dot layer, a green quantum dot layer, and a blue quantum dot layer, respectively, which are not limited by the embodiments of the present disclosure. The auxiliary layer 202 can prevent the material 203a′ of the first color quantum dot layer from remaining in the second sub-pixel region 2041b and the third sub-pixel region 2041c, and can also prevent the material 203b′ of the second color quantum dot layer from remaining in the third sub-pixel region 2041c, thereby avoiding the problem of color mixing and improving the color gamut of quantum dot light-emitting device.

The quantum dot light-emitting device provided by at least one embodiment of the present disclosure and the manufacturing method thereof have at least one of the following beneficial technical effects.

(1) In the quantum dot light-emitting device provided by at least one embodiment of the present disclosure, the auxiliary layer firstly occupies the position where unnecessary quantum dot materials may remain, that is, the auxiliary layer can prevent the material of the first color quantum dot layer from remaining in the second sub-pixel region and the third sub-pixel region, and can also prevent the material of the second color quantum dot layer from remaining in the third sub-pixel region 2041c, so as to prevent the problem of color mixing, thereby improving the color gamut of the quantum dot light-emitting device and further improving the full-color performance of the quantum dot light-emitting device.

(2) In the quantum dot light-emitting device provided by at least one embodiment of the present disclosure, the thickness of the auxiliary layer is 1 nm to 5 nm, and the auxiliary layer within this thickness range can not only reduce or eliminate unnecessary quantum dot residues, but also ensure good electron transport performance, and the auxiliary layer within this thickness range can also simplify the preparation process and reduce the cost.

The following points need to be explained:

(1) The drawings of the embodiment of this disclosure only relate to the structure related to the embodiment of this disclosure, and other structures can refer to the general design.

(2) For the sake of clarity, in the drawings used to describe the embodiments of the present disclosure, the thickness of layers or regions is enlarged or reduced, that is, these drawings are not drawn to actual scale.

(3) In the case of no conflict, the embodiments of the present disclosure and the features in the embodiments can be combined with each other to obtain a new embodiment.

The above is only the specific implementation of this disclosure, but the scope of protection of this disclosure is not limited thereto, and the scope of protection of this disclosure should be subject to the scope of protection of the claims.

1. A quantum dot light-emitting device, comprising: an electron transport layer, an auxiliary layer, and a quantum dot light-emitting layer which are sequentially stacked, wherein the quantum dot light-emitting layer comprises quantum dots, and surfaces of the quantum dots are provided with a first ligand, and the first ligand comprises a first functional group connected to the quantum dots and a second functional group away from the quantum dots; surfaces of the quantum dots in contact with the first ligand have a compound formed by a metal element and a nonmetallic element, and a material of the auxiliary layer comprises at least one selected from a group consisting of a compound containing the second functional group, a compound containing the metal element, and a compound containing the nonmetallic element.

2. The quantum dot light-emitting device according to claim 1, wherein the second functional group is an amino group, and the compound containing the second functional group comprises compounds of alkyl fatty amines with less than 7 carbon atoms, compounds of aromatic amines with electron transport properties, compounds of aminosilane coupling agents, and compounds of quaternary ammonium salts.

3. The quantum dot light-emitting device according to claim 2, wherein the compounds of alkyl fatty amines with less than 7 carbon atoms comprise at least one selected from the group consisting of ethylamine, propylamine and butylamine; the compounds of aromatic amines with electron transport properties comprise at least one selected from the group consisting of aniline, phenylethylamine and amphetamine; the compounds of aminosilane coupling agents comprise N-β-(aminoethyl)-γ-aminopropyl methyl dimethoxysilane; the compounds of quaternary ammonium salts comprise at least one selected from the group consisting of tetramethylammonium chloride and tetraethylammonium chloride.

4. The quantum dot light-emitting device according to claim 1, wherein the first ligand is formed by the reaction of a second ligand under ultraviolet irradiation with an acid generator, and a structural formula of the first ligand comprises 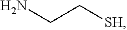
and a structural formula of the second ligand comprises

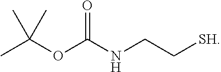

5. The quantum dot light-emitting device according to claim 1, wherein the material of the auxiliary layer comprises nanoparticles with the metal element or nanoparticles with the nonmetallic element.

6. The quantum dot light-emitting device according to claim 5, wherein a photoluminescence quantum yield of the nanoparticles with the metal element and a photoluminescence quantum yield of the nanoparticles with the nonmetallic element are both less than 2%.

7. The quantum dot light-emitting device according to claim 5, wherein a size of each of the nanoparticles with the metal element and a size of each of the nanoparticles with the nonmetallic element are both smaller than a size of each of the quantum dots.

8. The quantum dot light-emitting device according to claim 5, wherein each of the quantum dots has a core-shell structure, a material of a shell of each of the quantum dots and a material of a core of each of the quantum dots at least contain a same element, and the material of the auxiliary layer is the same as that of the core of each of the quantum dots.

9. The quantum dot light-emitting device according to claim 8, wherein the material of the auxiliary layer comprises nanoparticles formed of a same material of the core of each of the quantum dots, and a size of each of the nanoparticles of the auxiliary layer is the same or substantially the same as that of the core of each of the quantum dots.

10. The quantum dot light-emitting device according to claim 1, wherein a material of the quantum dots comprises a compound formed by a plurality of metal cations and an anions, and the compound containing the metal element comprises at least one selected from the group consisting of the plurality of metal cations.

11. The quantum dot light-emitting device according to claim 1, wherein a material of the quantum dots comprises a compound formed by a plurality of metal cations and anions, and the compound containing the nonmetallic element comprises the anions.

12. The quantum dot light-emitting device according to claim 5, wherein the compound containing the metal element or the compound containing the nonmetallic element comprises at least one selected from the group consisting of CdS, CdSe, InP, PbS, CsPbCl₃, CsPbBr₃ and CsPbl₃.

13. The quantum dot light-emitting device according to claim 1, wherein the material of the auxiliary layer comprises a compound containing the second functional group and a compound containing the metal element, and a ratio of a molar concentration of the compound containing the second functional group to a molar concentration of the compound containing the metal element is in a range from 10:1 to 30:1.

14. The quantum dot light-emitting device according to claim 1, wherein the material of the auxiliary layer comprises a compound containing the second functional group and a compound containing the nonmetallic element, and a ratio of a molar concentration of the compound containing the second functional group to a molar concentration of the compound containing the nonmetallic element is in a range from 10:1 to 30:1.

15. The quantum dot light-emitting device according to claim 1, wherein a thickness of the auxiliary layer is in a range from 1 nm to 5 nm.

16.-18. (canceled)

19. A manufacturing method of a quantum dot light-emitting device, comprising:
providing a base substrate;
sequentially forming an electron transport layer and an auxiliary layer on the base substrate, and forming a quantum dot light-emitting layer on the auxiliary layer by a photolithography process, wherein
the quantum dot light-emitting layer comprises quantum dots, and a surface of each of the quantum dots is provided with a first ligand, and the first ligand comprises a first functional group connected to the quantum dots and a second functional group away from the quantum dots; surfaces of the quantum dots in contact with the first ligand have a compound formed by a metal element and a nonmetallic element, and a material of the auxiliary layer comprises at least one selected from a group consisting of a compound containing the second functional group, a compound containing the metal element, and a compound containing the nonmetallic element.

20. The manufacturing method according to claim 19, wherein forming the electron transport layer comprises: applying an ethanol solution comprising ZnMgO nanoparticles or ZnO nanoparticles on the base substrate; baking at 80° C.˜100° C. for 8 min˜12 min.

21. The manufacturing method according to claim 19, wherein forming the auxiliary layer comprises: applying an ethanol solution of the compound containing the amino group with a molar concentration of 0.01 mol/L to 0.05 mol/L on the electron transport layer.

22. The manufacturing method according to claim 19, further comprising: forming a hole transport layer at a side of the quantum dot light-emitting layer away from the electron transport layer, and forming a hole injection layer at a side of the hole transport layer away from the electron transport layer.

23. The manufacturing method according to claim 22, further comprising: forming a first electrode between the electron transport layer and the base substrate, and forming a second electrode at a side of the hole injection layer away from the electron transport layer.
